(19) United States
(12) Patent Application Publication
(10) Pub. No.: US 2018/0009003 A1
(43) Pub. Date: Jan. 11, 2018

(54) PIEZOELECTRIC ELEMENT VIBRATION APPARATUS THAT PROVIDES REAL-TIME VIBRATION FEEDBACK

(71) Applicant: Jung-Hoon KIM, Daegu (KR)

(72) Inventor: Jung-Hoon KIM, Daegu (KR)

(21) Appl. No.: 15/545,205

(22) PCT Filed: Feb. 4, 2016
(86) PCT No.: PCT/KR2016/001247

§ 371 Date: Jul. 20, 2017

(30) Foreign Application Priority Data
Mar. 5, 2015 (KR) 10-2015-0031069

(51) Int. Cl. B06B 1/06; H01L 41/053

(52) U.S. Cl. CPC B06B 1/0603; H01L 41/0533

(57) ABSTRACT

Provided is a piezoelectric element vibration apparatus that generates vibration by applying a driving voltage to a piezoelectric vibrator, wherein a piezoelectric element layer is arranged on an electrode substrate made of a conductive material, an insulation member for preventing the applied driving voltage from leaking is formed on the piezoelectric element layer, and the piezoelectric element vibration apparatus has various types of forms in order to attach and install the piezoelectric vibrator. As a result, the piezoelectric element vibration apparatus has the effects wherein: installation is possible simply by attachment, thereby simplifying the assembly process; installation in any position is possible because the thickness of the piezoelectric element vibration device is made to be thin; the vibration volume can increase and the vibration noise can decrease while minimizing the thickness.

### TECHNICAL FIELD

The present invention relates to a vibration apparatus, and more particularly, to a piezoelectric element vibration apparatus that provides real-time vibration feedback to generate vibration via a piezoelectric effect.

### BACKGROUND ART

Nowadays, as a virtual reality realization technology is developed, a user wants more concrete and realistic information through virtual reality. One of technologies developed to meet this requirement is a haptic technology that transmits tactile feedback to the user by vibration. A simple haptic technology is a notification function using a vibration motor that is widely used in a mobile phone at present, and has also been widely applied to various fields such as, for example, a medical simulator and a game appliance.

In particular, in the future, a haptic device will be basically mounted, in addition to a monitor and a speaker, as an output device of a computing device. This is because there are advantages in that the tactile recognition rate of the user is high by installing the haptic device in a portable electronic appliance and in that the haptic device exhibits excellent interaction with IT devices.

A vibration motor of an existing mobile terminal, which is a concrete example of application of haptic technology to a portable electronic appliance such as a smart phone, adds a vibration sound and an image output from the mobile terminal to allow the user to feel the sound and the image stereoscopically.

A conventional haptic technology has not been able to transfer realistic feelings as a result of designing a waveform so as to create a digital waveform (mainly, PWM or sine wave) in order to produce a necessary effect, and then storing the same in a storage device so as to use the stored simple waveform when necessary.

As an example of a vibration motor installed in a mobile terminal, a “Minute Linear Vibration Motor” of Patent No, 10-793682, registered by the applicant of the present invention, has been disclosed.

However, in the vibration motor for the mobile terminal, when a vibration apparatus is installed in the mobile terminal, which has a small installation space, it is difficult to arrange constituent elements with regard to determination of a vibration generation position. In addition, in the case of a linear motor, it is necessary to load and drive a pre-stored waveform at a particular frequency, which complicates an execution circuit therefor.

In addition, the response time of a vibration motor is slow due to the use of attractive force and repulsive force of a coil and a magnet, which makes it difficult to ensure a feeling of simultaneity, and the magnitude of vibrations is insufficient due to the reduced size of the vibration motor.

### DISCLOSURE

### Technical Problem

Therefore, it is one object of the present invention to provide a piezoelectric element vibration apparatus for providing real-time vibration feedback, which is of an ultra-thin type and is easy to install while assuring free arrangement of constituent elements in an installation space therefor.

In addition, another object of the present invention is to provide a piezoelectric element vibration apparatus, which may increase the magnitude of vibration thereof, but may reduce noise due to vibration, and may prevent damage thereto due to a shock of being dropped.

### Technical Solution

To achieve the above-described object, in accordance with one aspect of the present invention, to accomplish the above and other objects, there is provided a piezoelectric element vibration apparatus that provides real-time vibration feedback, wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material, wherein the piezoelectric element layer (6) is provided with an insulation member (10) for preventing the applied driving voltage from leaking, and wherein the piezoelectric element vibration apparatus includes leg portions (8) formed on a bottom of the piezoelectric vibrator (2)(2a)(2b) by extending the electrode substrate (4) for realizing installation of the piezoelectric vibrator (2)(2a)(2b) via attachment.

In accordance with another aspect of the present invention, there is provided a piezoelectric element vibration apparatus that provides real-time vibration feedback, wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material, wherein the piezoelectric element layer (6) is provided with an insulation member (10) for preventing the applied driving voltage from leaking, and wherein the piezoelectric element vibration apparatus includes an insulated fixing housing (18) provided under the electrode substrate (4) for realizing installation of the piezoelectric vibrator (2)(2a)(2b) via attachment.

In accordance with another aspect of the present invention, there is provided a piezoelectric element vibration apparatus that provides real-time vibration feedback, wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material, wherein the piezoelectric element layer (6) is provided with an insulation member (10) for preventing the applied driving voltage from leaking, and wherein the piezoelectric element vibration apparatus includes brackets (22) fitted onto opposite ends of the piezoelectric vibrator (2)(2a)(2b) for realizing installation of the piezoelectric vibrator (2)(2a)(2b) via attachment.

In accordance with another aspect of the present invention, there is provided a piezoelectric element vibration apparatus that provides real-time vibration feedback, wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material, wherein the piezoelectric element layer (6) is provided with an insulation member (10) for preventing the applied driving voltage from leaking, wherein the electrode substrate (4) is provided on opposite ends thereof with elastic members (32) for increasing vibration efficiency of the piezoelectric vibrator (2)(2a)(2b), and wherein the piezoelectric element vibration apparatus includes a lower plate (36) provided under the elastic members (32) for realizing installation of the piezoelectric vibrator (2)(2a)(2b) via attachment.

In accordance with a further aspect of the present invention, there is provided a piezoelectric element vibration apparatus that provides real-time vibration feedback, wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material, wherein the piezoelectric element layer (6) is provided with an insulation member (10) for preventing the applied driving voltage from leaking, and wherein the piezoelectric element vibration apparatus includes a soft case (38) configured to surround the entire piezoelectric vibrator (2)(2a)(2b) for increasing a magnitude of vibration, reducing vibration noise, and realizing installation of the piezoelectric vibrator (2)(2a)(2b) via attachment.

### Advantageous Effects

According to the present invention, when a piezoelectric element vibration apparatus is installed in a mobile terminal, simplified installation via attachment is possible, which may simplify an installation process. In addition, the piezoelectric element vibration apparatus may be installed at any position inside the mobile terminal owing to a reduced thickness thereof, and may provide a user with a haptic signal by fast vibration response.

In addition, the piezoelectric element vibration apparatus of the present invention may increase the magnitude of vibration and reduce vibration noise while minimizing the size thereof, and may prevent damage to a piezoelectric vibrator due to a shock of being dropped.

### DESCRIPTION OF DRAWINGS

FIG. 1 is a perspective view illustrating the configuration of a piezoelectric element vibration apparatus that provides real-time vibration feedback according to one exemplary embodiment of the present invention,

FIG. 2 is a cross-sectional view illustrating a unimorph-type piezoelectric element vibration apparatus according to an embodiment of the present invention,

FIG. 3 is a view illustrating the use state of piezoelectric element vibration apparatus illustrated in FIG. 2,

FIG. 4 is a view illustrating the configuration of a bimorph-type piezoelectric element vibration apparatus according to another embodiment of the present invention,

FIGS. 5 to 6b are views illustrating the configuration of a multimorph-type piezoelectric element vibration apparatus according to a further embodiment of the present invention, and

FIGS. 7 to 26 are views illustrating the installation configuration of a piezoelectric vibrator according to various embodiments of the present invention.

### BEST MODE

Hereinafter, exemplary embodiments of the present invention will be described in detail with reference to the accompanying drawings.

A piezoelectric element vibration apparatus that provides real-time vibration feedback according to the present invention is a vibration means that generates vibration using a reverse piezoelectric effect.

A piezoelectric effect is one in which a voltage is generated at the time that a piezoelectric material is elastically deformed upon receiving force applied thereto, whereas a reverse piezoelectric effect is one in which a piezoelectric material is elastically deformed when a voltage is applied thereto. Examples of devices using the piezoelectric effect may include an ignition piezoelectric element (e.g., an electric lighter or an ignition-type gas stove), a pressure sensor, and an accelerometer, and examples of devices using the reverse piezoelectric effect may include an actuator and a piezoelectric motor.

To be precise, the vibration apparatus of the present invention realizes a vibration means using the reverse piezoelectric effect, and generates vibration using the principle whereby a piezoelectric element layer, formed of a piezoelectric material, is elastically deformed when a voltage is applied thereto. Representative examples of the piezoelectric material may include PZT (Pb(Ti,Zr)O₃), which is a composite ceramic, and barium titanate (BaTiO₃), which is a ferroelectric, and piezoelectric ceramics are formed using the same.

Vibration apparatuses using the piezoelectric effect are broadly divided into, for example, a unimorph-type, a bimorph-type, and a multimorph-type, and the bimorph-type vibration apparatuses are divided into a serial-type and a parallel-type according to the polarization direction.

In the present invention, configurations for installing various types of piezoelectric vibrators such as, for example, unimorph-type, bimorph-type and multimorph-type piezoelectric vibrators in a casing inside a mobile terminal are disclosed.

The mobile terminal may be a portable terminal having a call function (e.g., a smart phone), a medical appliance, a tablet PC, a game appliance, a vibrating mouse, a vibrating remote controller, a vibrating keypad, or a protective case for a portable terminal, and may include any electronic appliance for providing a user with vibration feedback.

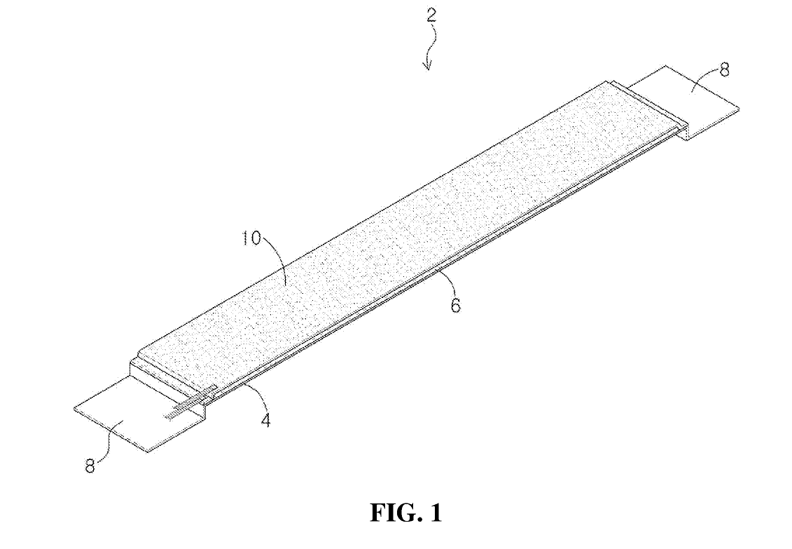

FIG. 1 illustrates the configuration of a unimorph-type piezoelectric element vibration apparatus according to one embodiment of the present invention. Referring to FIG. 1, in the present invention, a piezoelectric vibrator 2 is formed by disposing a piezoelectric element layer 6 on the top of an electrode substrate 4, which is formed of a material having high electrical conductivity.

According to the embodiment of the present invention, when “+” and “−” voltages are alternately applied to an upper electrode and a lower electrode of the piezoelectric element layer 6 of the piezoelectric vibrator 2, the piezoelectric vibrator 2 undergoes bending by expansion and contraction thereof and generates vibration according to the frequency of the applied driving voltage. Since the “+” and “−” voltages are alternately applied to the upper and lower surfaces of the piezoelectric element layer 6, the voltages are also applied to the electrode substrate 4, which is attached to the lower surface of the piezoelectric element layer 6 via adhesion.

In the present invention, in order to reduce the thickness of the entire piezoelectric vibrator 2, the voltages are applied to each of the electrode substrate 4 and the upper electrode of the piezoelectric element layer 6, which take the form of a flexible printed circuit board (FPCB). As needed, voltages may be applied using electric wires.

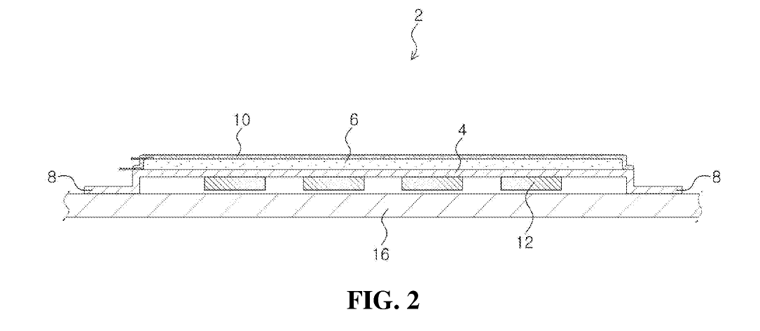

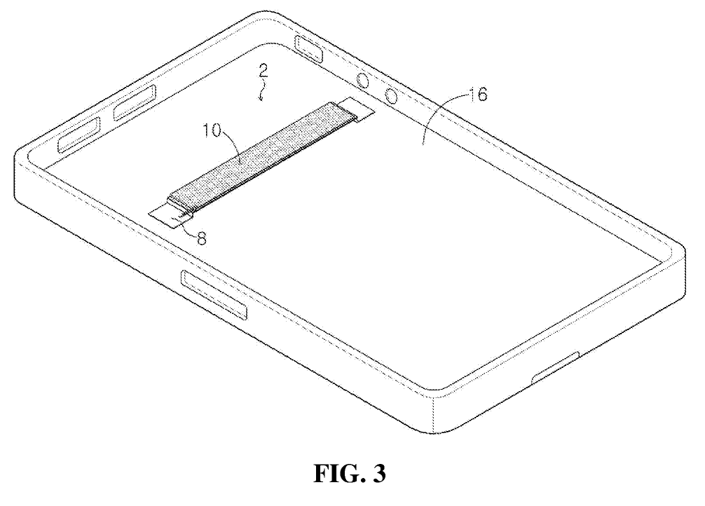

FIG. 2 is a cross-sectional view illustrating the installation of the piezoelectric vibrator 2 according to the embodiment of the present invention, and FIG. 3 is a view illustrating the use state of the piezoelectric vibrator 2 installed in a mobile terminal. An insulation member 10 is attached to the piezoelectric element layer 6 in order to prevent the driving voltage applied to the top of the piezoelectric element layer 6 from leaking into the mobile terminal. The insulation member 10 may be realized by attaching an insulation film, or by forming an insulation coating using, for example, epoxy or urethane.

In addition, a Poron tape may be further provided on the top of the piezoelectric element layer 6, on which the insulation member 10 has been provided, in order to exert an insulation function and to absorb noise generated in the piezoelectric vibrator 2.

The Poron tape is a thin urethane foam tape having a high-density cell structure, and exerts a noise absorption function as well as an insulation function, thereby being capable of reducing vibration noise of the piezoelectric vibrator 2 and preventing damage to the piezoelectric vibrator 2 by absorbing external shocks.

The electrode substrate 4 of the present invention may be formed of, for example, brass, stainless steel, Ni-alloy, or aluminum. Multiple weight pieces 12 are attached at predetermined positions on the bottom of the electrode substrate 4 in order to increase vibration generated when a voltage is applied. Although the piezoelectric vibrator 2 vibrates itself by the vertical bending displacement thereof, the magnitude of vibration transferred to the mobile terminal is weak. Therefore, the magnitude of vibration to be generated may be increased by attaching the weight pieces 12, each having a predetermined weight, to the piezoelectric element layer 6.

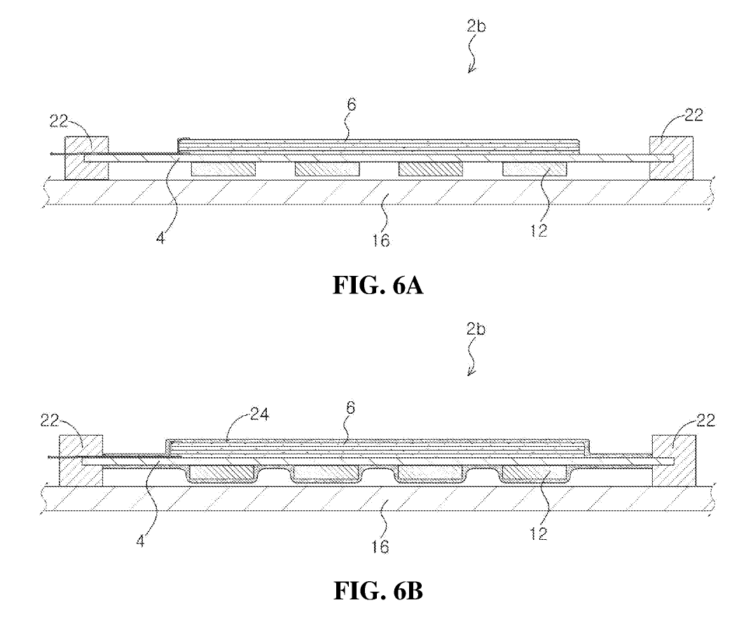

In the present invention, in order to attach the piezoelectric vibrator 2 to a casing 16 inside the mobile terminal, leg portions 8 are formed as bent extensions of the electrode substrate 4. As illustrated in FIG. 2, the leg portions 8 are formed to extend outward from the piezoelectric vibrator 2. In the case where the piezoelectric vibrator is installed in a small space inside the mobile terminal, as illustrated in FIG. 6, the leg portions may extend in the inward direction of the piezoelectric vibrator 2 in order to reduce the installation space therefor. The leg portions 8 may be attached to the casing 16 inside the mobile terminal using an adhesive or a piece of double-sided tape, or may be attached via welding, so as to realize fixing of the piezoelectric vibrator 2.

In consideration of the fact that the “+” and “−” voltages are alternately applied to the electrode substrate 4, in order to prevent the current applied to the electrode substrate 4 from leaking to the casing 16 inside the mobile terminal, the extended leg portions 8 may be insulated by an insulation coating, which is formed by coating a synthetic resin material such as, for example, silicon, urethane, epoxy, polyester, or acryl.

In addition, a coating layer formed of a soft synthetic resin or a synthetic rubber may be formed on the surface of the piezoelectric element layer 6 so as to alleviate noise generated during vibration and to exert an insulation effect. Examples of a constituent material of the coating layer may include soft epoxy, soft urethane, and silicon.

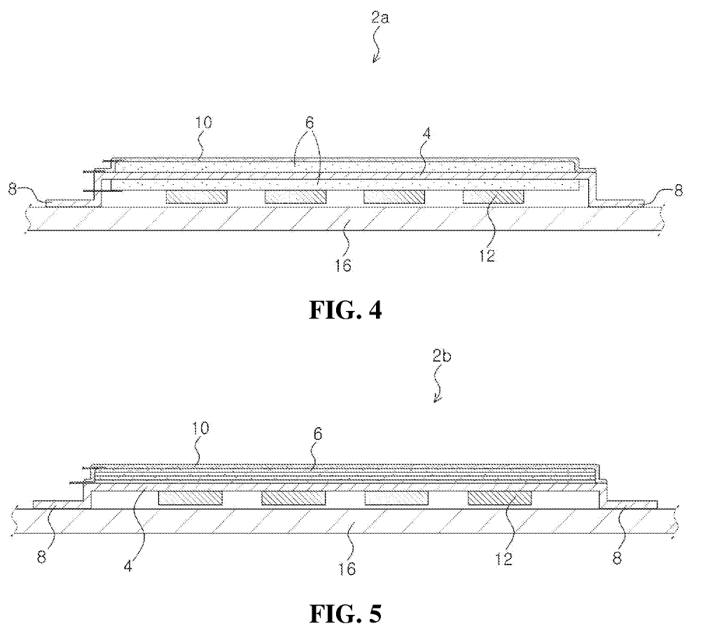

Although the unimorph-type piezoelectric element vibration apparatus according to one embodiment of the present invention has been described above, piezoelectric vibrators 2a and 2b may be formed as a bimorph-type piezoelectric element vibration apparatus in which two piezoelectric element layers 6 are disposed with the electrode substrate 4 interposed therebetween, as illustrated in FIG. 4, and a multimorph-type piezoelectric element vibration apparatus in which multiple piezoelectric element layers 6 are stacked one above another on the top of the electrode substrate 4, as illustrated in FIG. 5, and then may be installed in the mobile terminal.

FIGS. 6a and 6b illustrate another embodiment with regard to installation of the piezoelectric vibrator 2b. When the piezoelectric vibrator 2b is formed as the multimorph-type piezoelectric element vibration apparatus, brackets 22 may be formed on opposite ends of the piezoelectric vibrator 2b in order to attach and install the piezoelectric vibrator 2b to the casing 16 inside the mobile terminal.

The brackets 22 are fitted onto and coupled to opposite ends of the electrode substrate 4, and the piezoelectric vibrator 2b is fixed by directly attaching both brackets 22 to the inner surface of the casing 16.

Here, as illustrated in FIG. 6b, a piece of protective tape 24 may be attached to the outer surface of the piezoelectric vibrator 2b. The protective tape 24 may surround and be attached to one surface or both surfaces of the piezoelectric vibrator 2b, and may function to prevent damage to the piezoelectric element layer 6 and separation of the weight pieces 12 due to, for example, vibration of the piezoelectric vibrator 2, falling of the mobile terminal, or external shocks, and to exert an insulation effect.

After the protective tape 24 is attached and then the brackets 22 are fitted onto and installed to opposite ends of the piezoelectric vibrator 2b, the brackets 22 may be installed inside the mobile terminal.

The protective tape 24 may be attached even in the case where the piezoelectric element layer 6 is formed in a unimorph-type or a bimorph-type, and may be attached so as to surround the entire piezoelectric vibrator 2, 2a or 2b.

When the piezoelectric element layer 6 is formed in a multimorph-type as illustrated in FIGS. 6a and 6b, the size and thickness of the piezoelectric vibrator 2b may be reduced. Accordingly, when the piezoelectric vibrator is attached in a small installation space inside the mobile terminal, spatial limitation depending on the installation position may be reduced, which may allow the piezoelectric vibrator to be attached at any of various positions.

Although the brackets 22 are provided in order to attach and install the multimorph-type piezoelectric vibrator 2 as described above, the unimorph-type and bimorph-type piezoelectric vibrators 2 and 2a may also be fixed by fitting and coupling the brackets 22 onto opposite ends of the piezoelectric vibrator so as to attach and install the piezoelectric vibrators 2 and 2a.

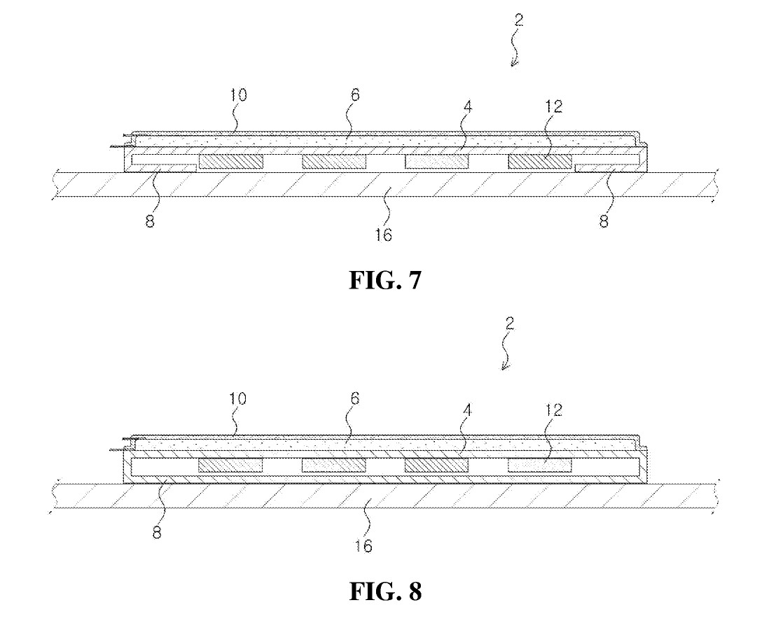

FIGS. 7 and 8 illustrate the installation configuration in which the shape of the electrode substrate 4 according to the present invention is modified in various ways to realize installation of the piezoelectric vibrator 2 to the casing 16 inside the mobile terminal.

In the piezoelectric vibrator 2 illustrated in FIG. 7, opposite ends of the electrode substrate 4 are bent to extend in the inward direction of the piezoelectric vibrator 2, and the resulting leg portions 8 are attached to the casing 16 so as to fix the piezoelectric vibrator 2. Since the leg portions 8 are bent in the inward direction of the piezoelectric vibrator 2, the piezoelectric vibrator 2 may occupy a reduced installation space when it is attached to the casing 16 inside the mobile terminal, thus ensuring efficient spatial utilization.

FIG. 8 illustrates the installation configuration of the piezoelectric vibrator 2 according to another embodiment of the present invention. In this embodiment, the electrode substrate 4 is formed into a box shape to realize the attachment of the piezoelectric vibrator 2 to the casing 16 inside the mobile terminal. The leg portions 8, which extend from opposite ends of the electrode substrate 4, are connected to each other so that the entire lower surface of the piezoelectric vibrator 2 is attached to the casing 16. Thereby, the leg portions 8 may increase the area over which the piezoelectric vibrator 2 is attached to the casing 16, which may ensure stronger attachment and fixing of the piezoelectric vibrator 2.

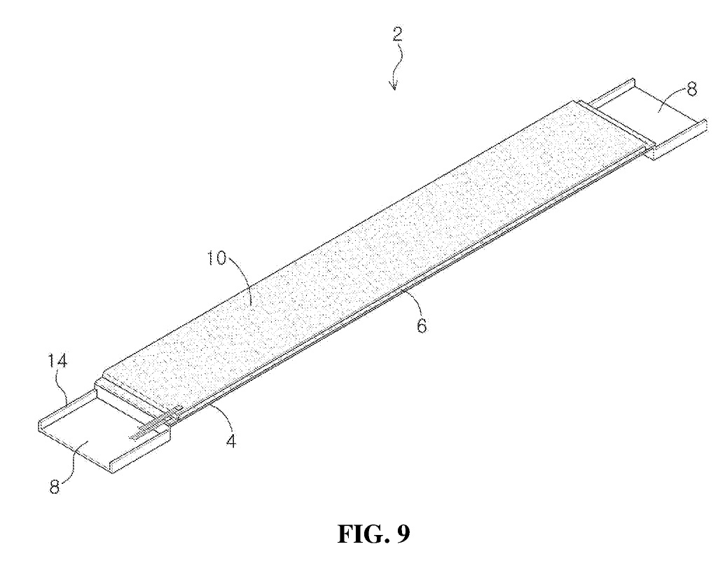

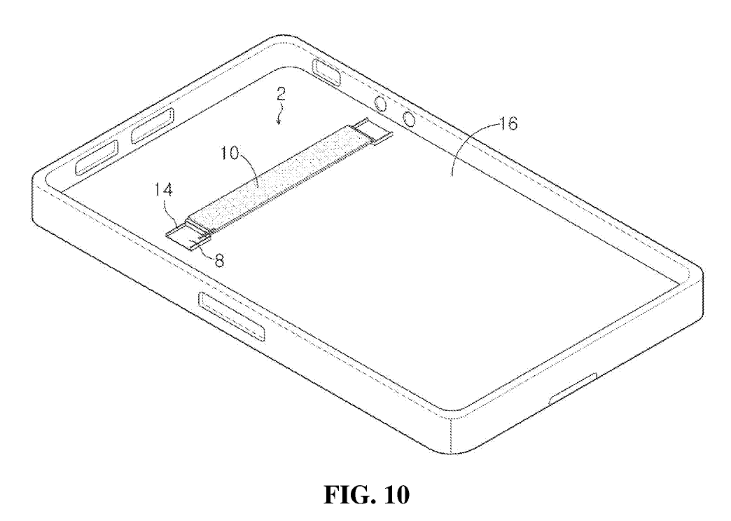

FIGS. 9 and 10 illustrate an alternative embodiment of the present invention. The piezoelectric vibrator 2, which is generally installed in an electronic appliance such as a mobile terminal, has a very small size, and in particular, the electrode substrate 4 of the present invention has a small thin-film shape having a thickness within a range from about 0.1˜0.3 T. The electrode substrate 4 having a thin-film shape has a risk of being wrinkled or deformed upon handling. When the piezoelectric vibrator 2 is installed to the casing 16 by attaching the leg portions 8, which are formed as bent extensions of the thin-film-shaped electrode substrate 4, the leg portions may not be able to support force and thus may not properly perform the function of fixing the piezoelectric vibrator 2.

In the present invention, support members 14 are provided in order to firmly support the leg portions 8 formed on opposite ends of the electrode substrate 4. The support members 14 are formed by bending opposite side surfaces of each leg portion 8 so that the leg portion 8 has a “U”-shaped cross-sectional shape. When the leg portions 8 are provided with the support members 14, opposite ends of the piezoelectric vibrator 2 are firmly fixed when vibration occurs in the state in which the piezoelectric vibrator is attached to the casing 16 inside the mobile terminal, and the thin-film-shaped electrode substrate 4 may not be easily wrinkled or deformed during handling of the piezoelectric vibrator 2 in an assembly process.

The piezoelectric vibrator 2 of the present invention undergoes vertical bending by expansion and contraction thereof when vibration occurs. The height of the support members 14 may be set to secure the space in which bending of the piezoelectric vibrator 2 may occur, in consideration of the bending range and the thickness of the weight pieces 12.

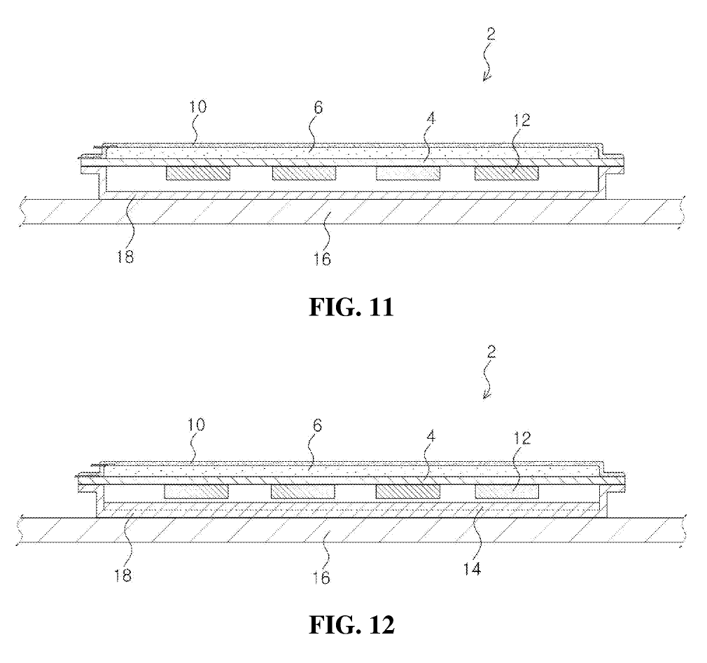

Although the piezoelectric vibrator 2 is installed by attaching the leg portions 8, which are formed as extensions of the electrode substrate 4, to the casing 16 in the embodiment of the present invention, as illustrated in FIG. 11, in order to install the piezoelectric vibrator 2 to the casing 16, a fixing housing 18 having a bent portion may be provided via a separate process in order to fix the piezoelectric vibrator.

The fixing housing 18 is attached by an adhesive or fixed by welding to the bottom of the electrode substrate 4, and the piezoelectric vibrator 2 is installed by attaching the lower surface of the fixing housing 18 to the casing 16. The fixing housing 18 may be formed of a high-strength material since it does not need to use the same material as the electrode substrate 4. In addition, since the fixing housing 18 is fabricated via a separate process, the process of insulating the fixing housing 18 may be simplified, and thus the process of fabricating the piezoelectric vibrator 2 may be simplified. In addition, when the fixing housing 18 is formed using a non-conductive material, it is possible to prevent the current applied to the electrode substrate 4 from moving to the fixing housing 18 and leaking to the casing 16.

Even in the case where the piezoelectric vibrator 2 is installed to the casing 16 using the fixing housing 18, as illustrated in FIG. 12, the support members 14 may be provided on the top of the fixing housing 18.

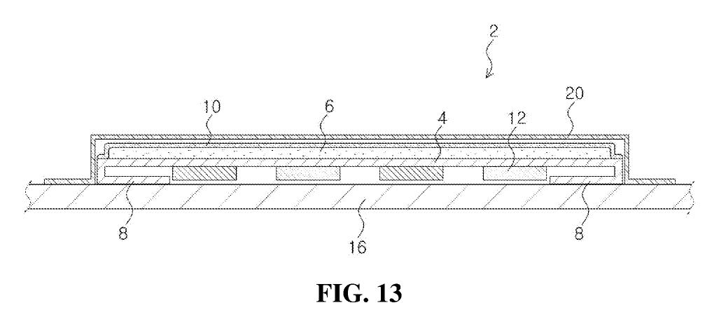

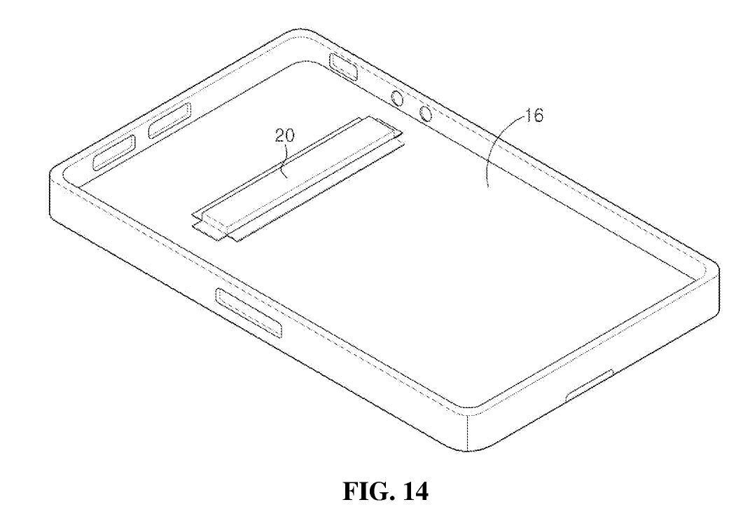

In the present invention, as illustrated in FIGS. 13 and 14, in order to suppress a vibration sound generated in the piezoelectric vibrator 2 attached to the casing 12, a separate soundproof case 20 is provided to cover the top of the piezoelectric vibrator 2. The soundproof case 20 may be formed of a metal plate, a plastic material, or a rubber material, and in particular, the soundproof case 20 may exert an increased effect of suppressing a sound generated during vibration when it is formed of a plastic material or a rubber material.

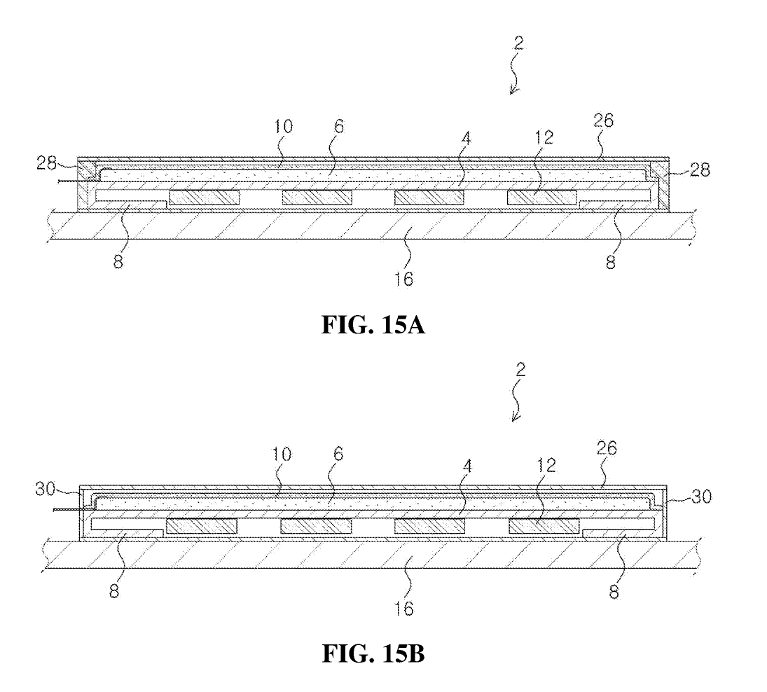

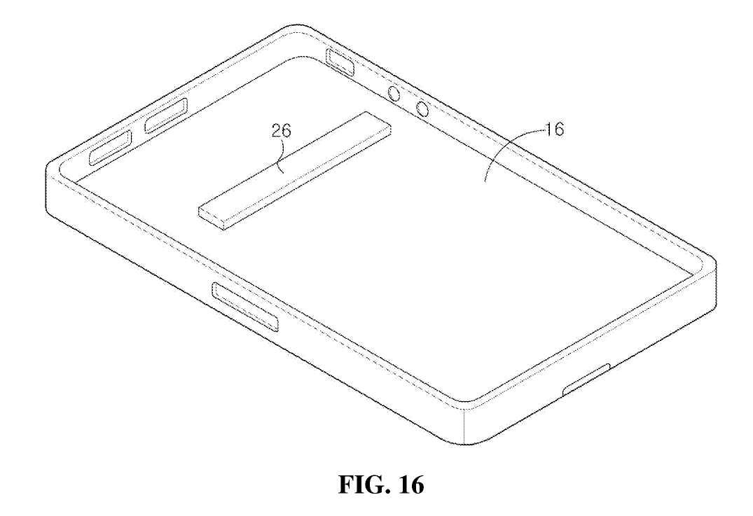

In addition, as illustrated in FIGS. 15a to 16, a vibration module case 26, into which the piezoelectric vibrator 2 may be fitted and installed, may be provided. After the piezoelectric vibrator 2 is fitted into and fixed in the vibration module case 26, the vibration module case 26 may be attached and fixed to the inner surface of the casing 16.

Explaining this in more detail, the piezoelectric vibrator 2 is fitted into one side of the tubular vibration module case 26 having an inner space defined therein so as to be accommodated in the inner space of the vibration module case 26. The vibration module case 26 may be formed of, for example, aluminum, stainless steel, an iron plate, or an article molded from synthetic resin.

After the piezoelectric vibrator 2 is fitted into the vibration module case 26, as illustrated in FIG. 15a, opposite ends of the vibration module case 26 are finished using sealing members 28. The sealing members 28 may be formed of, for example, silicon, UV adhesive, or epoxy. When opposite ends of the vibration module case 26 are finished using the sealing members 28, the sealing members 28 perform a soundproof function of preventing a sound wave generated by vibration of the piezoelectric vibrator 2 from leaking outward. In addition, when the piezoelectric vibrator 2 is fitted into the vibration module case 26, a self-protection function may be achieved.

In addition, as illustrated in FIG. 15b, blocking plates 30 may be formed on opposite ends of the vibration module case 26 so as to seal the piezoelectric vibrator 2 fitted and installed in the vibration module case.

The blocking plates 30 may be integrally formed with the vibration module case 26, or may be separately installed. In the state in which the piezoelectric vibrator 2 is fitted into and installed in the vibration module case 26 having open opposite ends, the blocking plates 30 close the respective open ends, thereby performing a soundproof function of preventing a vibration sound wave from leaking outward.

Once the piezoelectric vibrator 2 has been fitted in the vibration module case 26, the lower surface of the vibration module case 26 is attached and fixed to the inner surface of the casing 16 using an adhesive. The adhesive for fixing the vibration module case 26 may be a piece of double-sided tape, or may be, for example, an epoxy-based or acryl-based adhesive.

When the entire lower surface of the vibration module case 26, in which the piezoelectric vibrator 2 is inserted, is attached and fixed to the casing 16, the attachment area may be increased, which may ensure stable fixing. Thereby, the effect of transferring vibration generated in the piezoelectric vibrator 2 to the mobile terminal through the casing 16 is increased. In addition, when the piezoelectric vibrator 2 is installed in and integrally formed with the vibration module case 26 as described above, the working time taken in the process of attaching the vibration apparatus to the mobile terminal may be reduced.

Although FIGS. 15 and 16 illustrate the piezoelectric vibrator 2 having the leg portions 8 for the attachment of the piezoelectric vibrator 2 so as to be fitted into and installed in the vibration module case 26, the vibration module case may also be used in the case where opposite ends of the piezoelectric vibrator are fitted into the brackets 22 to thereby be attached to the casing 16, as illustrated in FIGS. 6a and 6b.

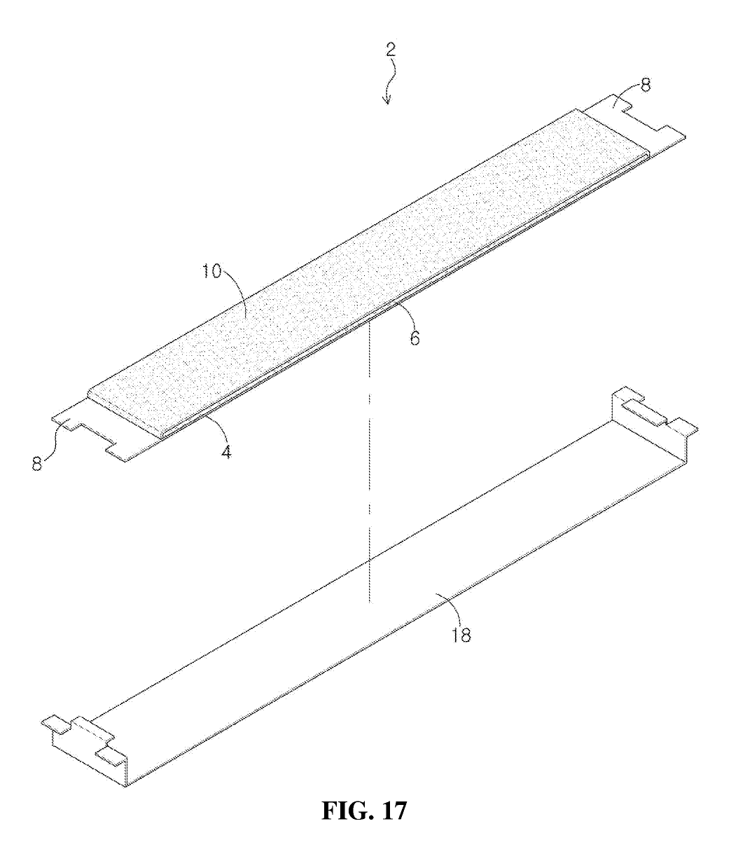

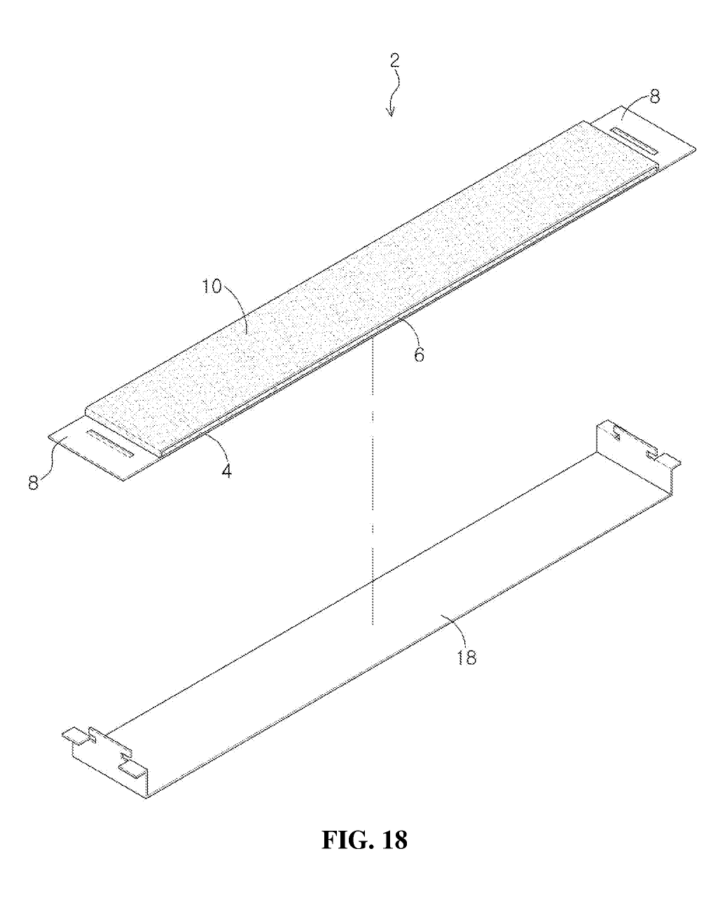

FIGS. 17 and 18 illustrate a fixing structure of the piezoelectric vibrator 2 according to various embodiments of the present invention.

In the case where the fixing housing 18 is provided to fix the piezoelectric vibrator 2 as illustrated in FIGS. 11 and 12 according to the present invention, opposite ends of the piezoelectric vibrator 2 may be completely fixed to the fixing housing 18 so that the amplitude of vibration is limited.

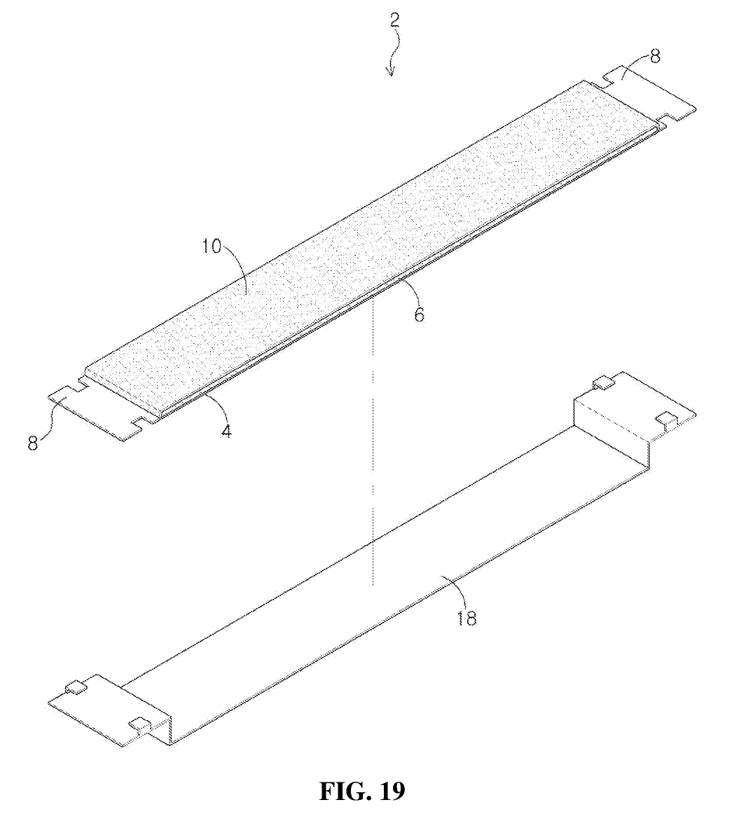

Accordingly, when the piezoelectric vibrator 2 is configured so as to be fixed via the fitting structure illustrated in FIGS. 17 to 19, opposite ends of the piezoelectric vibrator 2 may form free ends, rather than being completely fixed. Thereby, the vibration amplitude caused by the vertical bending displacement of the piezoelectric vibrator 2 is not limited, which enables variable vibration control and results in an increased magnitude of vibration.

In the case where opposite ends of the piezoelectric vibrator 2 are fixed via the fitting structure described above, a post-process of folding wing pieces formed on the ends of the fixing housing 18 to prevent separation of the piezoelectric vibrator 2 fitted therein is required.

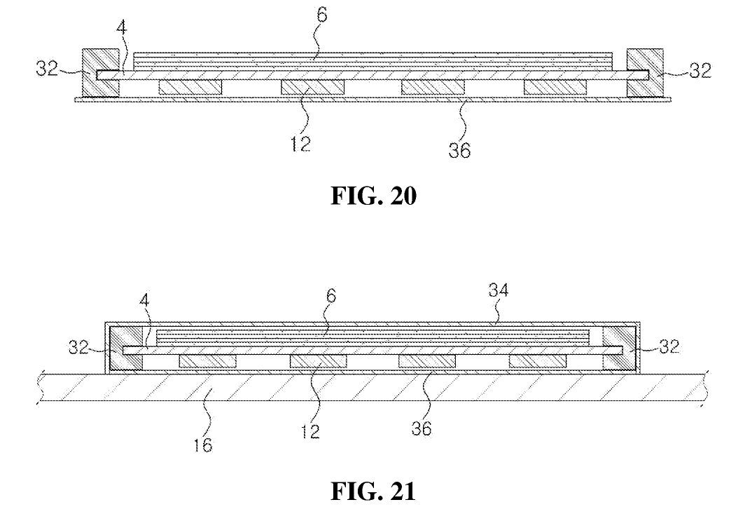

FIGS. 20 and 21 illustrate another embodiment of the piezoelectric vibrator 2b according to the present invention.

In the present invention, in order to increase the vibration efficiency of the piezoelectric vibrator 2b, elastic members 32 are provided on opposite ends of the electrode substrate 4. The elastic members 32 are formed of, for example, a synthetic resin such as silicon or urethane, a synthetic rubber or a natural rubber, and may be formed of any other soft elastic material.

The elastic members 32 may be formed on opposite ends of the electrode substrate 4 via adhesion, coupling, or injection molding, and may be thicker than the weight pieces 12 on the bottom of the electrode substrate 4 so as to ensure the vertical bending displacement of the piezoelectric vibrator 2b.

When the soft elastic members 32 are formed on opposite ends of the electrode substrate 4, the vibration efficiency of the weight pieces 12 may be increased when the weight pieces 12 vibrate due to the bending of the piezoelectric element layer 6 and the electrode substrate 4, and there is no limitation on resonance frequency owing to the flexibility of the electrode substrate 4, which enables variable vibration control of various frequencies. In addition, vibration noise due to the bending displacement of the piezoelectric element layer 6 and the electrode substrate 4 may be alleviated.

A lower plate 36 may be further provided below the electrode substrate 4, to which the elastic members 32 are installed, in order to install the piezoelectric vibrator 2b to the casing 16. The piezoelectric vibrator 2b is attached and fixed by attaching the lower plate 36 to the casing 16 using an adhesive.

In addition, as illustrated in FIG. 21, a cover 34 may be provided over the piezoelectric vibrator 2b attached to the casing 16 so as to surround the entire piezoelectric vibrator 2b, in order to prevent damage to the piezoelectric vibrator 2b due to a shock of being dropped and to reduce noise due to vibration.

The cover 34 may be formed of a metal plate, a plastic material or a rubber material, and in particular, the cover 34 may exert an increased effect of suppressing a sound generated during vibration when it is formed of a plastic material or a rubber material.

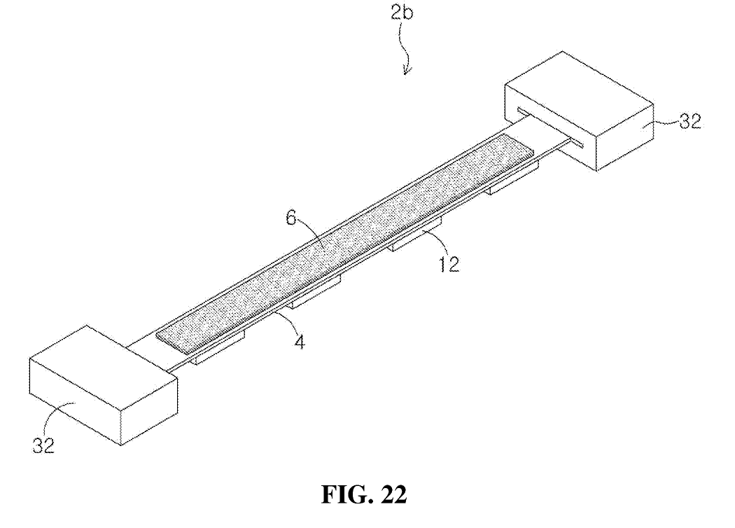

FIGS. 22 to 24 illustrate another form of the electrode substrate 4 that constitutes the piezoelectric vibrator 2b.

In the present invention, the electrode substrate 4 is formed to have a small width, in order to increase the vibration force of the piezoelectric vibrator 2b without increasing the size of the piezoelectric vibrator 2b or to reduce the size of the piezoelectric vibrator 2b while maintaining the same vibration force.

Referring to FIGS. 22 to 24, in the embodiment of the present invention, the piezoelectric vibrator 2b may be configured as a multimorph-type that exerts a large vibration force. As such, the piezoelectric element layer 6 may have a reduced size, and thus the width of the electrode substrate 4 may be reduced by the size of the area in which no piezoelectric element layer 6 is attached.

In the case where the piezoelectric vibrator 2b is attached inside an electronic appliance having a small inner space, such as a mobile terminal, as illustrated in FIG. 22, by minimizing opposite edge portions of the electrode substrate 4 on which no piezoelectric element layer 6 is attached, the volume of the piezoelectric vibrator 2b may be reduced and thus an available space is created in the electronic appliance, which ensures easy installation of other constituent elements.

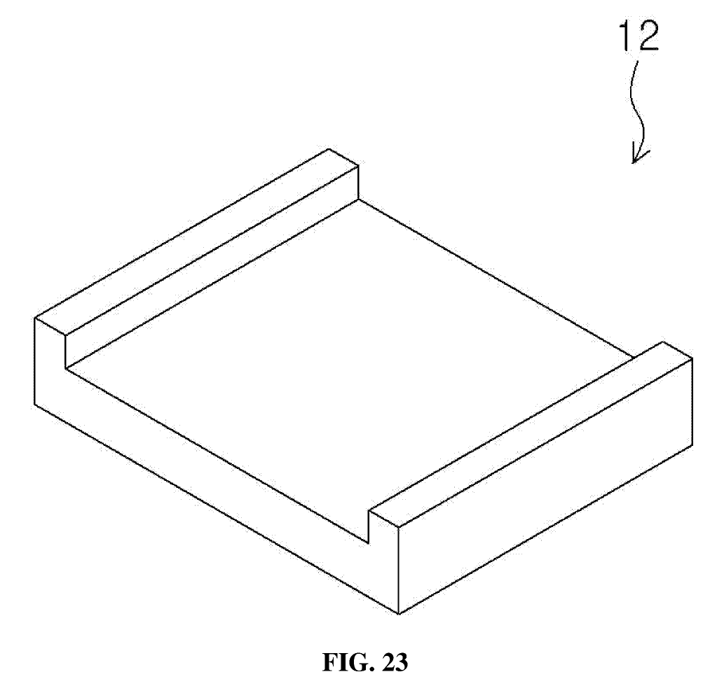

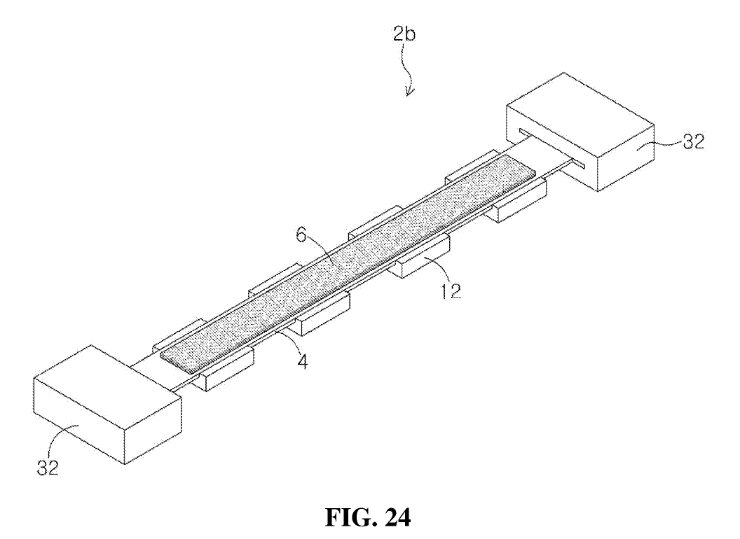

In addition, in order to utilize the available space created when the width of the electrode substrate 4 is reduced, the weight pieces 12, which have the shape illustrated in FIG. 23, may be attached to the electrode substrate 4 so as to form the piezoelectric vibrator 2b having the shape illustrated in FIG. 24. The weight of the weight pieces 12 may be increased so as to exert an increased vibration effect.

That is, even if the piezoelectric element layer 6 provides a consistent magnitude of vibration, the vibration efficiency may be increased when the weight of the weight pieces 12 attached to the electrode substrate 4 is increased. That is, the vibration effect may be increased even if the size of the piezoelectric vibrator 2b is reduced.

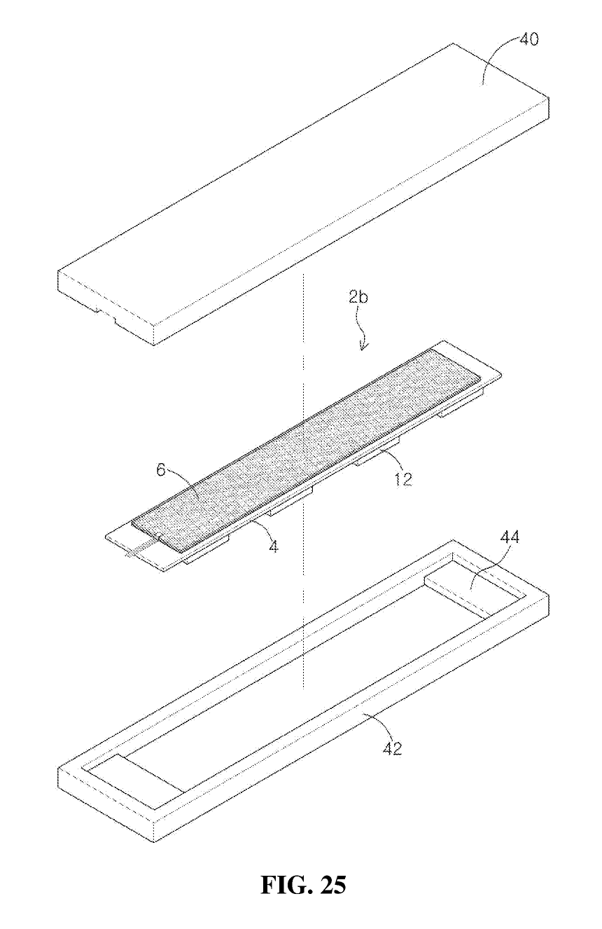

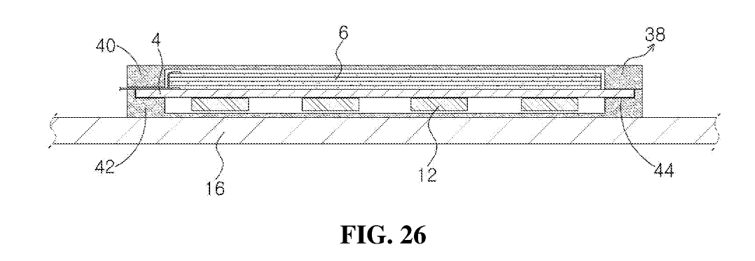

FIGS. 25 and 26 illustrate the configuration of the piezoelectric element vibration apparatus according to another embodiment of the present invention.

The piezoelectric vibrator 2b of the present invention may include a case 38, which may increase the magnitude of vibration, but may reduce noise due to vibration, and may attach and fix the piezoelectric vibrator 2b inside the mobile terminal.

The case 38 may be formed of a soft material such as a natural rubber or a synthetic rubber, and in particular, may be formed of, for example, silicon, neoprene, EPDM, fluoro rubber, or acryl rubber, among various types of available synthetic rubber. In addition, the case 38 may be formed of any other material so long as it has elasticity, such as a soft synthetic resin.

The case 38 of the present invention has the functions of the aforementioned members, i.e. the bracket 22 for attaching and fixing the piezoelectric vibrator 2b, the elastic member 32 for increasing the vibration efficiency, and the cover 34 for reducing vibration noise. When the case 38 is integrally formed to surround the piezoelectric vibrator 2b, a fabrication process may be simplified.

Considering the configuration of the case 38, the case includes an upper coupling portion 40 and a lower coupling portion 42, which are coupled to each other so as to surround the piezoelectric vibrator 2b, and the lower coupling portion 42 is provided on opposite ends thereof with seating portions 44, on which the electrode substrate 4 is seated.

Since the upper and lower coupling portions 40 and 42 are coupled so that the entire piezoelectric vibrator 2b is surrounded by a soft rubber material, opposite ends of the piezoelectric vibrator 2b are fixed via the coupling of the case 38.

When opposite ends of the piezoelectric vibrator 2b are fixed by the soft case 38, the vibration efficiency may be increased due to amplification by elasticity upon vibration, and there is no limitation on resonance frequency due to the flexibility of the electrode substrate 4, which enables vibration control of various frequencies.

In addition, vibration noise due to the bending displacement of the piezoelectric element layer 6 and the electrode substrate 4 may be alleviated.

In addition, since the entire piezoelectric vibrator 2b is surrounded and sealed by the upper and lower coupling portions 40 and 42, which are formed of a soft rubber material, the vibration sound of the piezoelectric vibrator 2b is not transferred to the soft case 38, which may reduce the noise of the piezoelectric vibrator 2b. In addition, since the piezoelectric vibrator 2b is protected by the case 38 formed of a rubber material, the soft case 38 serves to absorb, for example, a falling shock applied to the piezoelectric vibrator 2b, thereby preventing damage to the piezoelectric vibrator 2b.

The embodiments of the present invention do not limit the shape of the piezoelectric element layer 6 to the particular shapes illustrated in the drawings, and in various embodiments, the piezoelectric element layer 6 may be shaped to suit the unimorph-type, bimorph-type and multimorph-type piezoelectric vibrators 2, 2a and 2b. In addition, in addition to the bender-type piezoelectric vibrators 2, 2a and 2b illustrated in the embodiments of the present invention, the piezoelectric vibrators 2, 2a and 2b may be of a disc type.

Hereinafter, embodiments for installing the piezoelectric vibrator 2, 2a or 2b of the present invention to various electronic appliances so as to enable the transfer of a vibration response will be described. In addition to the embodiments described below, the present invention may be applied to various electronic appliance for transferring a vibration response to a user.

The piezoelectric vibrator 2, 2a or 2b of the present invention may be installed in the mobile terminal to transfer a fast vibration response to the user, and may be effectively installed in a mobile terminal having a small installation space, since the thickness thereof is drastically reduced compared to that of a conventional vibration motor.

In addition, the piezoelectric vibrator may provide the user with a feeling of simultaneity of a sound and an image owing to the fast response time thereof, and may provide the user with a realistic experience since it enables control to adjust the magnitude and speed of vibration within a wide frequency bandwidth range.

The piezoelectric vibrator 2, 2a or 2b of the present invention may be installed inside a vibrating mouse and may provide a feeling of simultaneity and a realistic experience depending on the user mouse operation by transferring a fast vibration response corresponding to displayed visual information to the user's hand.

When the piezoelectric vibrator 2, 2a or 2b of the present invention is installed in the vibrating mouse, various vibrations that suit visual information may be transferred to the hand, and an operation feeling may be transferred as a vibration response to the user when the user clicks the mouse.

The piezoelectric vibrator 2, 2a or 2b of the present invention may be installed in a smart input device, which interacts with a smart TV, for example, a keypad or a remote controller. Thereby, when a button of the smart input device is operated, the operation feeling may be transferred to the end of the finger, which may ensure accurate signal input of the smart input device having a reduced thickness.

In addition, the piezoelectric vibrator may transfer screen information output via the smart TV as vibration feedback to the user, and in particular, may transfer vibration corresponding to a game image output on a screen to the user, thereby providing the user with a realistic experience and a feeling of simultaneity owing to the fast vibration response.

The piezoelectric vibrator 2, 2a or 2b of the present invention may be installed in a controller of a game appliance such as a PSP or Nintendo of Sony, and may transfer a vibration response corresponding to a game image to the user in real time when the user operates the game appliance, thereby providing a realistic experience.

In addition, the piezoelectric vibrator 2, 2a or 2b of the present invention may achieve a faster response time and variable vibration within a wide frequency bandwidth range compared to a conventional vibration motor. Thereby, when the piezoelectric vibrator is installed in a game controller, the piezoelectric vibrator may provide a feeling of simultaneity by a real-time vibration response and a realistic experience by variable vibration.

The piezoelectric vibrator 2, 2a or 2b of the present invention may be installed in a protective case for preventing damage to a portable terminal such as a smart phone. Thus, in the state in which the protective case is mounted in the smart phone, the piezoelectric vibrator may transfer a vibration that suits an output image and sound to the user in real time.

Even in the case where the user operates a game appliance via a smart phone, the piezoelectric vibrator may transfer real-time vibration feedback that suits a game image, thereby providing a realistic experience and a feeling of simultaneity.

The control of vibration feedback corresponding to the image and sound of the smart phone is realized by providing a separate control module for controlling the piezoelectric vibrator 2, 2a or 2b in the protective case of the portable terminal. Thereby, the piezoelectric vibrator provides vibration feedback upon receiving a vibration control signal from the smart phone in a wired or wireless manner.

In addition, the protective case for the portable terminal may be equipped with a large-capacity auxiliary battery that assists a main battery of the smart phone, and the auxiliary battery may be used upon discharge of the main battery or upon the supply of power required to vibrate the piezoelectric vibrator 2, 2a or 2b.

As described above, with regard to the installation of the piezoelectric element vibration apparatus of the present invention, the piezoelectric element vibration apparatus may be simply installed via attachment, which may simplify an assembly process, and may be installed at any position owing to the reduced thickness thereof.

In addition, the piezoelectric element vibration apparatus of the present invention may increase the magnitude of vibration, but may reduce vibration noise while minimizing the size thereof, and may prevent damage to the piezoelectric vibrator 2, 2a or 2b due to a shock of being dropped.

Although the concrete embodiments of the present invention have been described above in detail, the present invention may be modified and altered in various ways within the scope and range of the present invention. Hence, the scope of the present invention should not be defined by the embodiments described above, but be defined by the claims and equivalents thereof.

### INDUSTRIAL APPLICABILITY

A piezoelectric element vibration apparatus of the present invention may be installed in a mobile terminal such as, for example, a smart phone, a medical appliance, a tablet PC, a game appliance, a vibrating mouse, a vibrating remote controller, a vibrating keypad, and a protective case for a portable terminal, and may be used to provide vibration feedback.

1. A piezoelectric element vibration apparatus that provides real-time vibration feedback,
wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material,
wherein the piezoelectric element layer (6) is provided with an insulation member (10) for preventing the applied driving voltage from leaking, and
wherein the piezoelectric element vibration apparatus includes leg portions (8) formed on a bottom of the piezoelectric vibrator (2)(2a)(2b) by extending the electrode substrate (4) for realizing installation of the piezoelectric vibrator (2)(2a)(2b) via attachment.

2. The piezoelectric element vibration apparatus according to claim 1, wherein the leg portions (8) are configured so as to be bent in any one of an inward direction and an outward direction of the piezoelectric vibrator (2)(2a)(2b).

3. The piezoelectric element vibration apparatus according to claim 2, wherein the leg portions (8), which are bent in the inward direction of the piezoelectric vibrator (2)(2a)(2b), are connected to each other at opposite ends thereof so as to increase an adhesion area over which the piezoelectric vibrator is attached.

4. The piezoelectric element vibration apparatus according to claim 1, wherein each of the leg portions (8) is provided with support members (14) for firmly supporting the attached piezoelectric vibrator (2)(2a)(2b) in a fixed state, the support members being formed by bending opposite side surfaces of the leg portion so as to define an “U”-shaped form.

5. The piezoelectric element vibration apparatus according to claim 1, wherein the leg portions (8) are provided with an insulation coating, which is formed by coating any one of synthetic resin materials including silicon, urethane, epoxy, polyester, and acryl.

6. A piezoelectric element vibration apparatus that provides real-time vibration feedback,
wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material,
wherein the piezoelectric element layer (6) is provided with an insulation member (10) for preventing the applied driving voltage from leaking, and
wherein the piezoelectric element vibration apparatus includes an insulated fixing housing (18) provided under the electrode substrate (4) for realizing installation of the piezoelectric vibrator (2)(2a)(2b) via attachment.

7. The piezoelectric element vibration apparatus according to claim 6, wherein the fixing housing (18) is provided with a support member (14) for firmly supporting the attached piezoelectric vibrator (2)(2a)(2b) in a fixed state.

8. A piezoelectric element vibration apparatus that provides real-time vibration feedback,
wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material,
wherein the piezoelectric element layer (6) is provided with an insulation member (10) for preventing the applied driving voltage from leaking, and
wherein the piezoelectric element vibration apparatus includes brackets (22) fitted onto opposite ends of the piezoelectric vibrator (2)(2a)(2b) for realizing installation of the piezoelectric vibrator (2)(2a)(2b) via attachment.

9. A piezoelectric element vibration apparatus that provides real-time vibration feedback,
wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material,
wherein the piezoelectric element layer (6) is provided with an insulation member (10) for preventing the applied driving voltage from leaking,
wherein the electrode substrate (4) is provided on opposite ends thereof with elastic members (32) for increasing vibration efficiency of the piezoelectric vibrator (2)(2a)(2b), and
wherein the piezoelectric element vibration apparatus includes a lower plate (36) provided under the elastic members (32) for realizing installation of the piezoelectric vibrator (2)(2a)(2b) via attachment.

10. The piezoelectric element vibration apparatus according to claim 9, wherein the piezoelectric vibrator (2)(2a)(2b) is provided with a cover (34) for preventing damage to the piezoelectric vibrator (2)(2a)(2b) due to a shock of being dropped and reducing noise due to vibration.

11. (canceled)

12. The piezoelectric element vibration apparatus according to claim 9, wherein the piezoelectric vibrator (2)(2a)(2b) is provided with a vibration module case (26) for preventing damage to the piezoelectric vibrator (2)(2a)(2b) due to a shock of being dropped and reducing noise due to vibration.

13. A piezoelectric element vibration apparatus that provides real-time vibration feedback,
wherein the piezoelectric element vibration apparatus is configured to generate a vibration when a driving voltage is applied to a piezoelectric vibrator (2)(2a)(2b), which is formed by disposing a piezoelectric element layer (6) on an electrode substrate (4) formed of a conductive material,
wherein the piezoelectric element layer (6) is provided with an insulation member (10) for preventing the applied driving voltage from leaking, and
wherein the piezoelectric element vibration apparatus includes a soft case (38) configured to surround the entire piezoelectric vibrator (2)(2a)(2b) for increasing a magnitude of vibration, reducing vibration noise, and realizing installation of the piezoelectric vibrator (2)(2a)(2b) via attachment.

14. The piezoelectric element vibration apparatus according to claim 13, wherein the case (38) includes upper and lower coupling portions (40)(42) for surrounding the piezoelectric vibrator (2)(2a)(2b), and the lower coupling portion (42) is provided with a seating portion (44) on which the electrode substrate is seated.

15. The piezoelectric element vibration apparatus according to claim 13, wherein the case (38) is formed of any one of a natural rubber, a synthetic rubber and a synthetic resin.

16. The piezoelectric element vibration apparatus according to claim 9, wherein the piezoelectric vibrator (2)(2a)(2b) is provided with a weight piece 12 for increasing vibration, and the weight piece (12) is attached and fixed to one surface or both surfaces of the piezoelectric vibrator (2)(2a)(2b).

17. The piezoelectric element vibration apparatus according to claim 9, wherein the piezoelectric vibrator (2)(2a)(2b) is any one of unimorph-type, bimorph-type and multimorph-type piezoelectric element vibration apparatuses.

18. The piezoelectric element vibration apparatus according to claim 9, wherein the piezoelectric vibrator (2)(2a)(2b) is provided with a piece of protective tape (24), which is attached to one surface or both surfaces of the piezoelectric vibrator for preventing damage to the piezoelectric element layer (6) and also preventing separation of the weight piece (12).

19. The piezoelectric element vibration apparatus according to claim 9, wherein the piezoelectric vibrator (2)(2a)(2b) is provided on a surface thereof with a coating layer, which is formed using any one of a soft synthetic resin and a synthetic rubber for exerting insulation and alleviating a sound generated by vibration.

20. The piezoelectric element vibration apparatus according to claim 9, wherein the piezoelectric vibrator (2)(2a)(2b) is installed in a mobile terminal including a portable terminal having a call function, a medical appliance, a tablet PC, a game appliance, a vibrating mouse, a vibrating remote controller, a vibrating keypad, or a protective case for a portable terminal that provides vibration feedback.

21. The piezoelectric element vibration apparatus according to claim 13, wherein the piezoelectric vibrator (2)(2a)(2b) is provided with a weight piece 12 for increasing vibration, and the weight piece (12) is attached and fixed to one surface or both surfaces of the piezoelectric vibrator (2)(2a)(2b).

22. The piezoelectric element vibration apparatus according to claim 13, wherein the piezoelectric vibrator (2)(2a)(2b) is any one of unimorph-type, bimorph-type and multimorph-type piezoelectric element vibration apparatuses.

23. The piezoelectric element vibration apparatus according to claim 13, wherein the piezoelectric vibrator (2)(2a)(2b) is provided with a piece of protective tape (24), which is attached to one surface or both surfaces of the piezoelectric vibrator for preventing damage to the piezoelectric element layer (6) and also preventing separation of the weight piece (12).

24. The piezoelectric element vibration apparatus according to claim 13, wherein the piezoelectric vibrator (2)(2a)(2b) is installed in a mobile terminal including a portable terminal having a call function, a medical appliance, a tablet PC, a game appliance, a vibrating mouse, a vibrating remote controller, a vibrating keypad, or a protective case for a portable terminal that provides vibration feedback.
